(19) United States
(12) Patent Application Publication
(10) Pub. No.: US 2012/0307468 A1
(43) Pub. Date: Dec. 6, 2012

(54) ELECTRONIC APPARATUS

(75) Inventors: Tomotaka Suzuki, Nagoya (JP); Tsuneo Maebara, Nagoya (JP)

(73) Assignee: DENSO CORPORATION, Kariya-city (JP)

(21) Appl. No.: 13/485,980

(22) Filed: Jun. 1, 2012

(30) Foreign Application Priority Data
Jun. 3, 2011 (JP) 2011-124835

(51) Int. Cl. H05K 1/18

(52) U.S. Cl. 361/767

(57) ABSTRACT

An electronic apparatus includes a circuit board on which a plurality of electronic components are mounted, and a housing that is provided on the circuit board. The housing includes a mounting member that mounts the housing on the circuit board. The circuit board includes a plurality of circuit regions, an insulating region, and a mounting region. The plurality of electronic components is included in the plurality of circuit regions. The plurality of circuit regions are spaced from one another. The insulating region is located between adjacent circuit regions of the plurality of circuit regions to insulate between the adjacent circuit regions. In the mounting region, the mounting member is mounted on the circuit board. The mounting region is provided in the insulating region located between the adjacent circuit regions in a state where the housing is mounted on the circuit board.

### CROSS-REFERENCE TO RELATED APPLICATION

This application is based on and claims the benefit of priority from earlier Japanese Patent Application No. 2011-124835 filed Jun. 3, 2011, the description of which is incorporated herein by reference.

### BACKGROUND OF THE INVENTION

1. Technical Field of the Invention

The present invention relates to an electronic apparatus including a circuit board on which a plurality of electronic components are mounted and a housing which is provided on the circuit board.

2. Related Art

Circuit boards in which wiring patterns are arranged tend to suffer insulation breakdown between adjacent patterns. In a well-known technique for preventing such insulation breakdown, as disclosed in a patent document JP-A-S64-072584, for example, a sufficient insulating distance is ensured between the adjacent patterns.

Specifically, the patent document JP-A-S64-072584 discloses a printed circuit board on which a control circuit of a high-frequency heating device is mounted. In the printed circuit board, slits each having a predetermined width, length and angle are provided between lands for inserting high-voltage components and between patterns to ensure a sufficient insulating distance.

For the purpose of providing a shield against electromagnetic waves, for example, circuit boards are often provided with a housing. In providing the housing on the circuit board, mounting members are used so that the housing is mounted on the circuit board. Accordingly, the circuit board is required to be provided with regions for installing respective mounting members. However, provision of such mounting regions may reduce the area on the circuit board for mounting electronic components, and may also reduce the density of integration of the circuit board. This can be applied to the printed circuit board having a configuration in which slits are provided between patterns as disclosed in the patent document JP-A-S64-072584.

### SUMMARY

It is thus desired to provide an electronic apparatus which is able to increase the area on a circuit board for mounting electronic components.

According to an exemplary aspect of the present disclosure, there is provided an electronic apparatus, comprising: a circuit board on which a plurality of electronic components are mounted; and a housing that is provided on the circuit board, wherein the housing includes a mounting member that mounts the housing on the circuit board, and the circuit board includes a plurality of circuit regions where the plurality of electronic components are included, the plurality of circuit regions being spaced from one another, an insulating region that is located between adjacent circuit regions of the plurality of circuit regions to insulate between the adjacent circuit regions, and a mounting region where the mounting member is mounted on the circuit board, the mounting region being provided in the insulating region located between the adjacent circuit regions in a state where the housing is mounted on the circuit board.

In the exemplary aspect set forth above, an insulating region is provided between adjacent circuit regions on the circuit board to insulate therebetween. Provision of the insulating region prevents the occurrence of insulation breakdown between the adjacent circuit regions to thereby prevent such inconveniences as malfunction of electronic components. Thus, reliability of the electronic apparatus is prevented from being deteriorated. In the exemplary aspect set forth above, a mounting region is provided in the insulating region located between adjacent circuit regions, in a state where the housing is installed on the circuit board. Thus, the insulating region on the circuit board is effectively used as a mounting region to thereby increase an area on the circuit board for mounting electronic components.

At least one of the plurality of circuit regions may include, for example, a drive circuit for driving a switching element and an electrical path (wiring pattern) for connecting a terminal of the switching element to the drive circuit.

In the exemplary aspect, the adjacent circuit regions of the plurality of circuit regions may include first adjacent circuit regions and second adjacent circuit regions, where a potential difference between the first adjacent circuit regions is larger than a potential difference between the second adjacent circuit regions; and the mounting member may be provided in the insulating region located between the first adjacent circuit regions.

The distance (insulating distance) necessary for preventing insulation breakdown between adjacent circuit regions tends to become longer as the potential difference between the circuit regions becomes larger. For this reason, the area of the insulating region located between circuit regions having a large potential difference tends to become larger than the area of the insulating region located between circuit regions having a smaller potential difference. In light of this, in the exemplary aspect set forth above, the insulating region located between the circuit regions having a large potential difference is used as a mounting region. Thus, the area for mounting electronic components on the circuit board is favorably suppressed from being limited by the provision of a mounting region. In other words, the area for mounting electronic components is increased.

When the potential difference between circuit regions is large, the area of the insulating region located between the circuit regions tends to become large. Therefore, a mounting region can be selected from the large insulating area on the circuit board. Thus, the degree of freedom is enhanced in determining a mounting region.

In the exemplary aspect, a through hole, through which a screw is inserted, may be formed in the insulating region located between the adjacent circuit regions; a screw hole, in which the screw is inserted via the through hole, may be formed in the mounting member; the mounting region may be a region that is enclosed by an outer edge of a portion of the mounting member in contact with the circuit board in a state where the housing is mounted on the circuit board by inserting the screw in the screw hole via the through hole; and a center of the through hole may be positioned on a central line passing through a central portion between a pair of lines that are determined by passing through parts of a pair of boundary lines of the adjacent circuit regions, the parts of the pair of boundary lines being opposed to and parallel with each other.

In providing a mounting region on a circuit board, a predetermined region near the mounting region may be required to be an insulating region to prevent the occurrence of insulation breakdown between circuit regions. In this case, there is a concern that the insulating region may be enlarged and thus the area for mounting electronic components may be limited.

In this regard, in the exemplary aspect set forth above, the center of a through hole is positioned on the center line. Accordingly, the insulating region is favorably suppressed from being enlarged by the provision of a mounting region on the circuit board. Thus, the area for mounting electronic components on the circuit board is favorably suppressed from being limited by the provision of the mounting region.

In the exemplary aspect, the mounting member may be made of conductive material; and the insulating region may include a region that is enclosed by an outer edge of the mounting member and a predetermined closed curve which is positioned outside from the outer edge of the mounting member on the circuit board and is determined by enclosing the mounting member.

In the exemplary aspect set forth above, a region defined between the outer edge of a mounting region and the closed curve is included in the insulating region. Thus, insulation breakdown that would have been caused between adjacent circuit regions via a mounting member is prevented from occurring.

In exemplary aspect, the mounting member may be made of non-conductive material; and the mounting region may be a region that is enclosed by an outer edge of a portion of the mounting member in contact with the circuit board in a state where the housing is mounted on the circuit board.

In the exemplary aspect set forth above, use of a mounting member made of a non-conductive material can reduce a mounting region and the insulating distance between circuit regions. Thus, the area for mounting electronic components on the circuit board is favorably suppressed from being limited by the provision of a mounting region.

In exemplary aspect, the circuit board may be a double-sided circuit board having a first surface and a second surface, the second surface being a rear surface with respect to the first surface, the plurality of electronic components being mounted on each of the first surface and the second surface; the plurality of circuit regions and the insulating region may be mounted on each of the first surface and the second surface; a through hole, through which a screw is inserted, may be formed in the insulating region located between the adjacent circuit regions; a screw hole, in which the screw is inserted via the through hole, may be formed in the mounting member; the housing may be mounted on the circuit board by inserting the screw in the screw hole via the through hole from a side of the second surface to a side of the first surface; the mounting region may include a first region and a second region, where the first region is a region that is enclosed by an outer edge of a portion of the mounting member in contact with the first surface in a state where the housing is mounted on the circuit board, and the second region is a region that is enclosed by an outer edge of a portion of a head of the screw in contact with the second surface in a state where the housing is mounted on the circuit board; and a first insulating distance and a second insulating distance are individually determined, where the first insulating distance is an insulating distance between the adjacent circuit regions between which the first region is placed and the second insulating distance is an insulating distance between the adjacent circuit regions between which the second region is placed.

In the exemplary aspect set forth above, the degree of freedom is enhanced in determining the insulating distance between circuit regions in each of the first surface and the second surface of the double-sided circuit board.

In exemplary aspect, a through hole, through which a screw is inserted, may be formed in the insulating region located between the adjacent circuit regions; a screw hole, in which the screw is inserted via the through hole, may be formed in the mounting member; the housing may be mounted on the circuit board by inserting the screw in the screw hole via the through hole; and the through hole may be formed at positions that are aligned on the circuit board.

In the exemplary aspect set forth above, the vibration resistance of a circuit board is maximized, for example, by forming each through hole according to the mode provided above.

The vibration resistance of a circuit board refers to proof stress of the circuit board, which is able to retain reliability of the circuit board when an external force is applied to the electronic apparatus.

### BRIEF DESCRIPTION OF THE DRAWINGS

In the accompanying drawings:

FIG. 1 is a plan view illustrating a circuit board for a power converter applied to an electronic apparatus according to a first embodiment of the present invention;

FIG. 2 is a plan view illustrating a mode of an arrangement of a high-voltage circuit region and a low-voltage circuit region in the circuit board;

FIG. 3 is a cross-sectional view taken along a line A-A of FIG. 2;

FIG. 4 is a plan view illustrating a mode of forming a mounting region in the circuit board;

FIG. 5 is a cross-sectional view illustrating a vicinity of a mounting region in a double-sided circuit board, according to a second embodiment of the present invention;

FIG. 6 is a plan view illustrating a mode of forming a mounting region in a circuit board, according to a third embodiment of the present invention; and

FIG. 7 is a plan view illustrating a mode of forming a mounting region in a circuit board according to a fourth embodiment of the present invention.

### DETAILED DESCRIPTION OF THE PREFERRED EMBODIMENTS

With reference to the accompanying drawings, hereinafter are described some embodiments of the present invention.

### First Embodiment

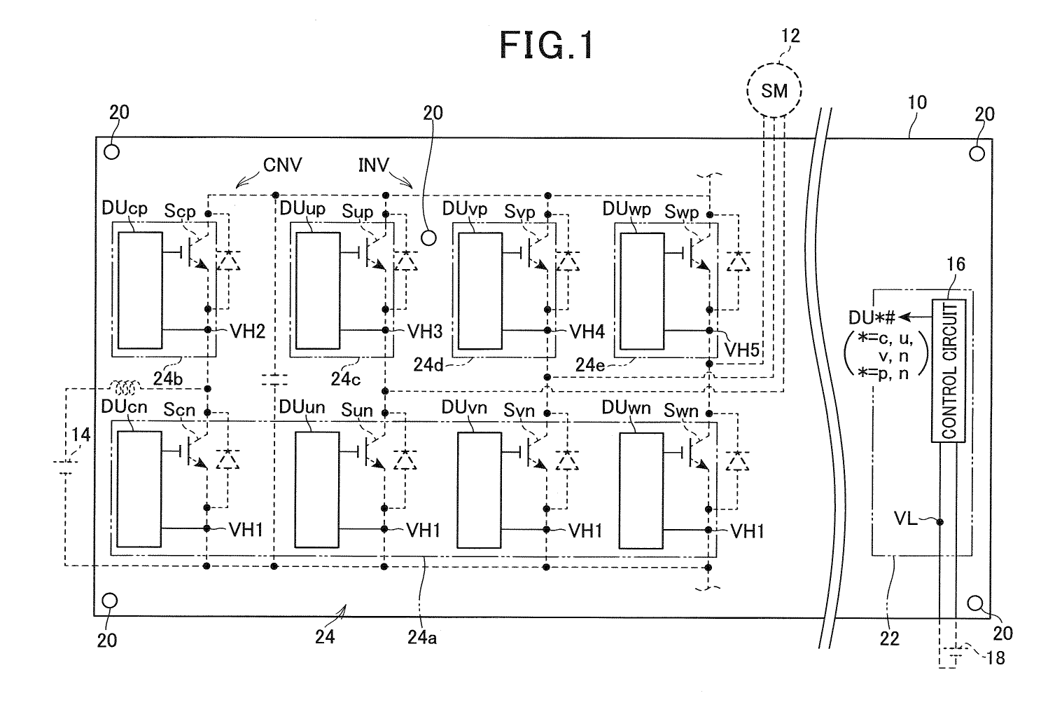

Referring to FIGS. 1 to 4, a first embodiment of the present invention is described. In the first embodiment, an electronic apparatus according to the present invention is applied to a power converter for a rotary machine, as a main engine, of a plug-in hybrid vehicle (PHV).

FIG. 1 is a diagram illustrating a general configuration of the power converter that includes a control system according to the first embodiment.

As shown in FIG. 1, the power converter includes a circuit board 10 that is provided with an inverter INV, a step-up converter CNV, a drive circuit (drive unit) for driving the inverter INV and the step-up converter CNV, and a housing (not shown) having an inner space where the circuit board 10 is accommodated.

The inverter INV and the step-up converter CNV electrically connect a motor-generator 12 as a main engine to a high-voltage battery 14.

The step-up converter CNV converts a direct current (DC) voltage from the high-voltage battery 14 to a predetermined DC voltage under drive control of switching elements Scp and Scn through drive circuits DUcp and DUup. Specifically, the step-up converter CNV is composed of a capacitor, a pair of switching elements Scp and Scn, and a reactor. The switching elements Scp and Scn are connected in parallel with the capacitor. The reactor connects a connecting point between the switching elements Scp and Scn with a positive terminal of the high-voltage battery 14. With the on/off operation of the switching elements Scp and Scn, the step-up converter CNV steps up the direct current (DC) voltage (e.g. 100 V or more) of the high-voltage battery 14 so as not to exceed a predetermined upper-limit voltage (e.g., 666 V).

The inverter INV converts the predetermined DC voltage from the step-up converter CNV to an alternating current (AC) voltage under control of switching elements Sup, Sun, Svp, Svn, Swp and Swn through drive circuits DUup, DUun, DUvp, DUvn, DUwp, DUwn. Specifically, the inverter INV is composed of a serial connection of switching elements Sup and Sun, a serial connection of switching elements Svp and Svn, and a serial connection of switching elements Swp and Swn. These serial connections have respective connecting points which are connected to respective U-, V- and W-phases of the motor-generator 12. The present embodiment is described assuming that insulated gate bipolar transistors (IGBTs) are used as the switching elements S*# (*=u, v, w, and c, #=p and n). Diodes are connected in anti-parallel with respective switching elements S*#.

The power converter also includes a second inverter (not shown) other than the inverter INV mentioned above. The second inverter is also connected to the step-up converter CNV to serve as an auxiliary engine that supplies/receives electric power to/from a motor-generator which is different from the motor-generator 12 mentioned above.

The circuit board 10 is a member having a rectangular shape in a plan view. Specifically, the circuit board 10 is formed of a rectangular insulating board on which wiring patterns made of a conductive material, such as copper, are arranged. The circuit board 10 is provided with drive units DU*#, a control circuit 16, and the like. The drive units DU*# have a function of driving the respective switching elements S*#.

The control circuit 16 is driven by a low-voltage battery 18 (e.g., of more than 10 V), as a power source, whose voltage across the terminals is significantly lower than that of the high-voltage battery 14. The control circuit 16 controls the inverter INV and the step-up converter CNV so that controlled value of the motor-generator 12 which is a controlled object is controlled to be desired value. Specifically, the control circuit 16 outputs operation signals to the drive units DU*# via an interface, not shown, which is provided with an insulating element, such as a photocoupler, to thereby control the switching elements Scp and Scn of the step-up converter CNV and the switching elements Sup, Sun, Svp, Svn, Sw and Swn of the inverter INV. High-potential side switching elements S*p and corresponding low-potential side switching elements S*n are turned on in an alternate manner.

The circuit board 10 is provided with a plurality of through holes 20 used for mounting the circuit board 10 on the housing. Specifically, the through holes 20 pass through the circuit board 10 in the direction of its thickness and each have a circular shape (true circular shape) in a plan view of the circuit board.

In the present embodiment, the circuit board 10 is provided with one low-voltage circuit region 22 and a plurality of high-voltage circuit regions 24. Each of the circuit regions 22 and 24 has a rectangular or square shape. The low-voltage circuit region 22 includes the control circuit 16 and an electrical path (wiring pattern) that connects the control circuit 16 to the low-voltage battery 18. Thus, the low-voltage circuit region 22 configures a part of a low-voltage system in the power converter, with the low-voltage battery 18 being provided as an electrical power source.

The high-voltage circuit regions 24 include the drive units DU*# and electrical paths (wiring patterns) that connect the drive units DU*# to gates and emitters of the respective switching elements S*#. Thus, the high-voltage circuit regions 24 configure a part of a high-voltage system in the power converter, with the high-voltage battery 14 being provided as an electrical power source. The high-voltage circuit regions 24 include a first high-voltage circuit region 24a and second, third, fourth and fifth high-voltage circuit regions 24b, 24c, 24d and 24e. The first high-voltage circuit region 24a includes the drive units DUcn, DUun, DUvn and Duwn corresponding to the respective low-potential side switching elements Scn, Sun, Svn and Swn. The second, third, fourth and fifth high-voltage circuit regions 24b, 24c, 24d and 24e include drive units DUcp, DUup, DUvp and Duwp corresponding to the switching elements Scp, Sup, Svp and Swp, respectively.

In the present embodiment, in the low-voltage circuit region 22, the potential of the electrical path connecting the control circuit 16 to the negative terminal of the low-voltage battery 18 is rendered to have a reference potential VL. Also, in the first high-voltage circuit region 24a, an emitter-side potential of each low-potential side switching element S*n is rendered to have a reference potential VH1. Further, in the high-voltage circuit regions 24b to 24e, emitter-side potentials of the respective high-potential side switching elements S*p are rendered to have reference potentials VH2 to VH5, respectively.

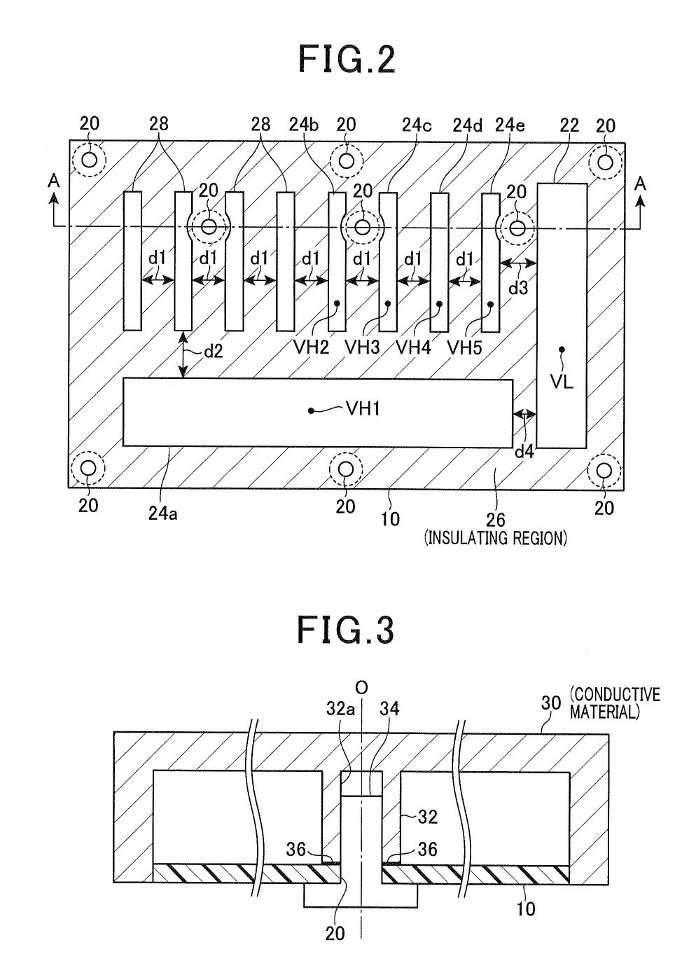

Referring to FIG. 2, hereinafter are specifically described a mode of arrangement of the low-voltage circuit region 22 and the high-voltage circuit regions 24 on the circuit board 10, and positions of forming the through holes 20. FIG. 2 is a plan view illustrating the circuit board 10. The housing covering the circuit board 10 is omitted from the figure.

First, a mode of arranging the low-voltage circuit region 22 and the high-voltage circuit regions 24 is described.

As shown in FIG. 2, the low-voltage circuit region 22 and the first to fifth high-voltage circuit regions 24a to 24e are provided being intervened by an insulating region 26 as indicated by the diagonal lines in the figure, so as to be spaced apart from each other. The insulating region 26 prevents the occurrence of insulation breakdown between adjacent circuit regions. Specifically, of the second to fifth high-voltage circuit regions 24b to 24e as well as sixth high-voltage circuit regions 28, those regions which are adjacent to each other are spaced apart from each other by a first insulating distance d1 in a longitudinal direction (horizontal direction as viewed in FIG. 2) of the circuit board 10. The sixth high-voltage circuit regions 28 are provided in addition to the first to fifth high-voltage circuit regions 24a to 24e to serve, for example, as circuit regions corresponding to respective switching elements provided to the second inverter mentioned above.

The first high-voltage circuit region 24a is provided being spaced apart from the second to fifth high-voltage circuit regions 24b to 24e and the sixth high-voltage circuit regions 28 by a second insulating distance d2 in the width direction of the circuit board 10 (vertical direction as viewed in FIG. 2). Also, the low-voltage circuit region 22 is provided being spaced part from the fifth high-voltage circuit region 24e by a third insulating distance d3 in the longitudinal direction of the circuit board 10. Further, the low-voltage circuit region 22 is provided being spaced part from the first high-voltage circuit region 24a by a fourth insulating distance d4 in the longitudinal direction of the circuit board 10. These first to fourth insulating distances d1 to d4 are determined so that the occurrence of insulation breakdown between adjacent circuit regions can be prevented.

Hereinafter is described how the first to fourth insulating distances d1 to d4 are determined in the present embodiment, taking as examples the low-voltage circuit region 22 and the first to fifth high-voltage circuit regions 24a to 24e.

In the present embodiment, the reference potential VL of the low-voltage circuit region 22 is set to a value larger than a minimum value Vmin of the reference potentials VH2 to VH5 that would be achieved by the second to fifth high-voltage circuit regions 24b to 24e, and lower than a maximum value Vmax of the reference potentials VH2 to VH5. Specifically, the reference potential VL of the low-voltage circuit region 22 is set to a value slightly larger than the minimum value Vmin. More specifically, the reference potential VL is set to a value lower than an average of the maximum and minimum values Vmax and Vmin. Accordingly, the reference potential VH1 of the first high-voltage circuit region 24a that includes wiring patterns for connecting the emitters of the low-potential side switching elements S*n to the respective drive units DU*n becomes equal to the minimum value Vmin of the reference potentials VH2 to VH5 that would be achieved by the second to fifth high-voltage circuit regions 24b to 24e.

By determining the reference potentials in this way, the maximum potential difference that would be caused between the low-voltage circuit region 22 and the fifth high-voltage circuit region 24e will be Vmax-VL. This is because, with respect to the reference potential VL of the low-voltage circuit region 22, the reference potential VH5 of the fifth high-voltage circuit region 24e will be Vmin or Vmax with the turning on or off of the switching element Swp.

The potential difference between the low-voltage circuit region 22 and the first high-voltage circuit region 24a will be VL-Vmin. This is because, with respect to the reference potential VL of the low-voltage circuit region 22, the reference potential VH1 of the first high-voltage circuit region 24a will be Vmin.

Further, the maximum potential difference that would be caused between the high-voltage circuit region 24a and the second to fifth high-voltage circuit regions 24b to 24e will be Vmax. This is because, with respect to Vmin of the reference potential VH1 of the first high-voltage circuit region 24a, the reference potentials VH2 to VH5 of the second to fifth high-voltage circuit regions 24b to 24e will be Vmin or Vmax with the turning on or off of the high-potential side switching elements S*p.

In addition, the maximum potential difference that would be caused between those circuit regions which are adjacent to each other among the second to fifth high-voltage circuit regions 24b to 24e will be Vmax-Vmin. This is because, with the turning on or off of the switching elements corresponding to those circuit regions which are adjacent to each other among the second to fifth high-voltage circuit regions 24b to 24e, the reference potential of each of the adjacent circuit regions will be Vmin or Vmax.

In general, an insulating distance tends to become larger as the potential difference between circuit regions becomes larger. In the present embodiment, the second, first, third and fourth insulating distances d2, d1, d3 and d4 are set to values incrementing in this order, based on the magnitude relationship in the maximum values of the above potential differences between adjacent circuit regions.

Hereinafter are described positions for forming the through holes 20.

In the present embodiment, one through hole 20 is formed at each of four corners of the circuit board 10. Also, one through hole 20 is formed near the center of each of two sides of the circuit board 10, which are opposed to each other in the width direction of the circuit board 10. Further, three through holes 20 are formed at a center portion of the circuit board 10. As shown in FIG. 2, the three through holes 20 at the center portion are formed in the insulating region between the sixth high-voltage circuit regions 28 and the second to fifth high-voltage circuit regions 24b to 24e so as to be aligned in the longitudinal direction of the circuit board 10. More specifically, the three though holes 20 are formed sandwiching a plurality of (three in FIG. 2) high-voltage circuit regions inbetween, and aligned in the longitudinal direction of the circuit board 10. These positions are derived from the calculation for obtaining conditions that maximize the vibration resistance of the circuit board 10 of the present embodiment. The vibration resistance here refers to proof stress of the circuit board 10, which can retain reliability of the circuit board 10 when an external force is applied to the power converter as the vehicle travels. High vibration resistance can prevent disconnection of the wiring patterns or separation of electronic components, such as a capacitor, which are mounted by soldering.

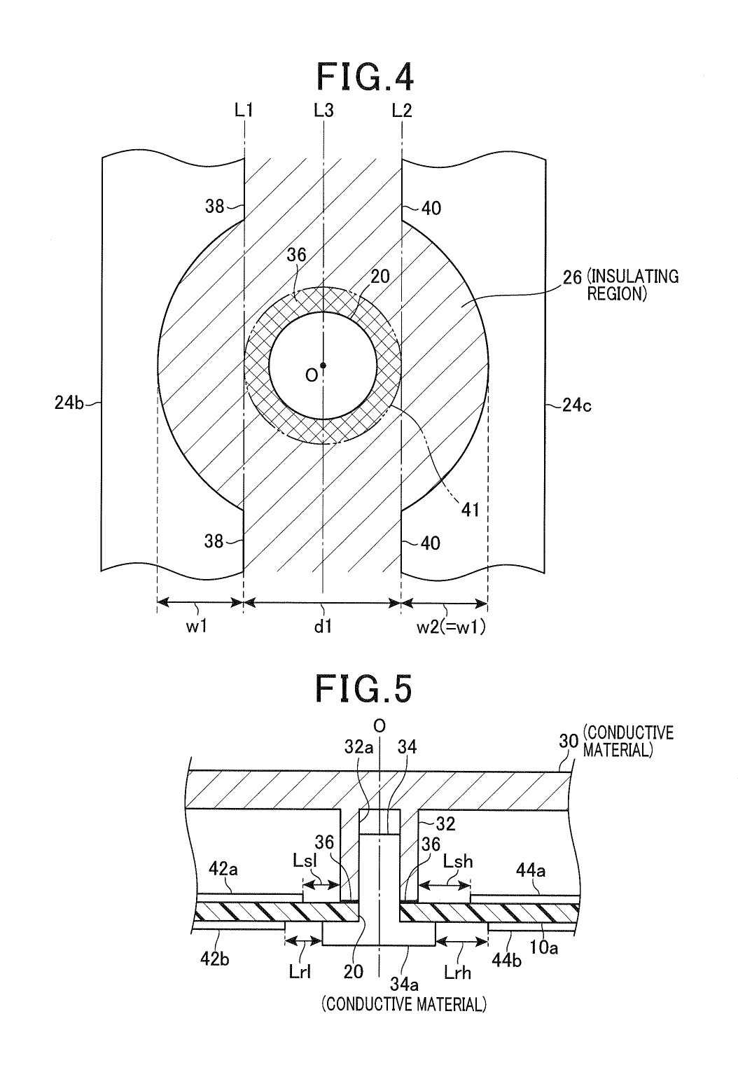

Referring to FIGS. 3 and 4, hereinafter is described a mode of mounting the housing on the circuit board 10, according to the present embodiment.

FIG. 3 is a cross-sectional view taken along a line A-A of FIG. 2. Specifically, FIG. 3 is a cross-sectional view taken along a plane passing through a center axis of a screw 34, the plane being substantially perpendicular to a plane parallel to the circuit board 10, in a state where the housing 30 is mounted on the circuit board 10.

As shown in FIG. 3, the housing 30 has a function, for example, of accommodating the circuit board 10 so as to be installed in a vehicle and of preventing electromagnetic waves from flowing between the circuit board and the outside. The housing 30 has a shape of a rectangular solid, with one face being open. The present embodiment is described assuming that the housing 30 is made of a conductive material (e.g., metallic material).

The housing 30 includes a plurality of mounting members (hereinafter referred to as boss(es) 32) which are integrated into the housing 30. The bosses 32 are also made of a conductive material and formed at positions corresponding to the respective through holes 20 of the circuit board 10. The bosses 32 correspond to cylindrical portions of the housing 30, each extending from the housing 30 (from an internal upper surface of the housing 30) toward the circuit board 10 along the center axis (the dash-single dot line in FIG. 3) which is substantially perpendicular to a plane parallel to the circuit board 10, in a state where the housing 30 is mounted on the circuit board 10. Each boss 32 is provided with a screw hole 32a therein which is coaxial with the cylindrical boss 32.

In mounting the housing 30 on the circuit board 10, each screw 34 is inserted into the screw hole 32a via the through hole 20 from the rear surface (lower surface of the circuit board 10 in FIG. 3) toward the front surface (upper surface of the circuit board 10 in FIG. 3) of the circuit board 10. Thus, each boss 32 is mounted on (secured to) the circuit board 10 to thereby mount the housing 30 on the circuit board 10. In the present embodiment, a region where the boss 32 contacts the circuit board 10 (a region defined between an inner edge of the through hole 20 and the dotted line indicated near the inner edge in FIG. 2) is hereinafter referred to as a contact region 36. It should be appreciated that the screw 34 is made of a conductive material (metallic material).

FIG. 4 is an enlarged view illustrating the vicinity of the through hole 20 formed between the second and third high-voltage circuit regions 24b and 24c shown in FIG. 2. In FIG. 4, the region indicated by the diagonal lines is the insulating region 26.

As shown in FIG. 4, the second and third high-voltage circuit regions 24b and 24c include boundary lines which are opposed to each other. These boundary lines include respective straight portions 38 and 40 which are parallel with each other keeping the first insulating distance d1 therebetween. FIG. 4 includes virtual lines L1 and L2 drawn along the straight portions 38 and 40, respectively, and a center line L3 drawn between the lines L1 and L2 so as to be parallel with the lines L1 and L2. The center line L3 is evenly distanced from the lines L1 and L2. Each through hole 20 is formed so that its center O is positioned on the center line L3. Thus, on the circuit board 10, the contact region 36 is defined between the inner edge of the through hole 20 and an outer edge (dash-double dot line in FIG. 4) of the boss 32, which is in contact with the circuit board 10. In the present embodiment, the region on the circuit board 10, which is enclosed by this outer edge of the boss 32, is referred to as a mounting region 41 (i.e., a region including the through hole 20 and the contact region 36).

The occurrence of insulation breakdown is required to be prevented. Insulation breakdown would be caused between the second and third high-voltage circuit regions 24b and 24c via the contact region 36 where the boss 32 made of a conductive material contacts the circuit board 10. In order to prevent the occurrence of insulation breakdown, in the present embodiment, the following region is ensured to be included in the insulating region 26. This region has a center coinciding with the center O of the through hole 20 and is defined between an outer edge of a circle having a radius w1+d1/2 and the outer edge of the mounting region 41 (contact region 36). The radius w1+d1/2 is rendered to be larger than the distance between the center O and the outer edge of the mounting region 41 (contact region 36). In this case, symbol w1 indicates a distance between the outer edge of the mounting region 41 (contact region 36) and the second high-voltage circuit region 24b.

In the present embodiment, the sum of the distance w1 and a distance w2 is rendered to be equal to the first insulating distance d1. The distance w1 is the distance between the outer edge of the contact region 36 and the second high-voltage circuit region 24b, and the distance w2 is a distance between the outer edge of the contact region 36 and the third high-voltage circuit region 24c. When the switching elements Scp and Sup are turned on/off, the maximum value of the potential difference between the second high-voltage circuit region 24b corresponding to the switching element Scp and the boss 32 becomes equal to the maximum value of the potential difference between the third high-voltage circuit region 24c corresponding to the switching element Sup and the boss 32. Accordingly, a relation w1=w2 is established.

According to the present embodiment specifically described above, the following advantages are obtained.

(1) The center O of the through hole 20 is positioned on the center line L3. Thus, the area for mounting electronic components on the circuit board 10 is favorably suppressed from being limited by the provision of the mounting region 41. In other words, the area for mounting electronic components is increased.

(2) The through holes 20 are also formed in the insulating region 26 located between the high-voltage circuit regions 24. Since the insulating region 26 located between the high-voltage circuit regions 24 tends to have a large area, the large area is used for forming the through holes 20 according to the mode described above. Thus, the area for mounting electronic components on the circuit board 10 is favorably suppressed from being limited by the provision of the mounting region 41.

As described above, as the potential difference between circuit regions becomes larger, the area of the insulating region 26 located between the circuit regions tends to become larger accordingly. Thus, the regions, or the positions, for forming the through holes 20 can be selected from the larger area ensured accordingly on the circuit board 10, owing to the tendency, thereby contributing to maximizing the vibration resistance of the circuit board. Accordingly, constraints in determining the positions of the through holes 20 are mitigated as much as possible. In other words, the degree of freedom is enhanced in determining the mounting regions 41.

(3) The through holes 20 are formed at positions on the circuit board 10, which positions maximize the vibration resistance of the circuit board 10. Thus, reliability of the circuit board 10 is enhanced.

### Second Embodiment

Referring to FIG. 5, hereinafter is described a second embodiment of the present invention, focusing on the differences from the first embodiment. In the second and the subsequent embodiments and modifications, the components identical with or similar to those in the first embodiment are given the same reference numerals for the sake of omitting unnecessary explanation.

In the second embodiment, a double-sided circuit board having front and rear surfaces on which electronic components can be mounted is used in place of the circuit board 10 of the first embodiment.

FIG. 5 is a cross-sectional view illustrating a circuit board 10a of the second embodiment. The diagram illustrated in FIG. 5 corresponds to the diagram illustrated in FIG. 2. In FIG. 5, low- and high-voltage circuit regions are indicated being imparted with a thickness.

As shown in FIG. 5, each of the front surface (first surface) and the rear surface (second surface) of the circuit board 10a is provided with the low- and high-voltage circuit regions. Specifically, the front surface is provided with a first low-voltage circuit region 42a and a first high-voltage circuit region 44a. Also, the rear surface is provided with a second low-voltage circuit region 42b and a second high-voltage circuit region 44b.

In the present embodiment, in a plan view of the front surface of the circuit board 10a, the distance from the outer edge of the contact region 36 to the first low-voltage circuit region 42a is a distance Lsl. Similarly, the distance from the outer edge of the contact region 36 to the first high-voltage circuit region 44a is a distance Lsh. Further, in a plan view of the rear surface of the circuit board 10a, the distance from the outer edge of a head 34a of the screw 34 to the second low-voltage circuit region 42b is a distance Lrl. Similarly, the distance from the outer edge of the head 34a to the second high-voltage circuit region 44b is a distance Lrh.

In the present embodiment, similar to the low-voltage circuit region 22 of the first embodiment, the first and second low-voltage circuit regions 42a and 42b have a reference potential VL. Also, of the reference potentials which the first and second high-voltage circuit regions 44a and 44b may have, a minimum value is rendered to be Vmin. Further, of the reference potentials which the first and second high-voltage circuit regions 44a and 44b may have, a maximum value is rendered to be Vmax.

In this case, a maximum value of the potential difference that would be caused between the boss 32 made of a conductive material and the first low-voltage circuit region 42a is equal to a maximum value of the potential difference that would be caused between the head 34a of the screw 34 made of a conductive material and the second low-voltage circuit region 42b. Accordingly, in the present embodiment, a relation Lsl=Lrl is established. It should be noted that the distance Lrl on the rear surface depends on the shape of the head 34a of the screw 34.

Further, a maximum value of the potential difference that would be caused between the boss 32 and the first high-voltage circuit region 44a is equal to a maximum value of the potential difference that would be caused between the head 34a of the screw 34 and the second high-voltage circuit region 44b. Accordingly, in the present embodiment, a relation Lsh=Lrh is established. It should be noted that, similar to the distance Lrl, the distance Lrh on the rear surface depends on the shape of the head 34a of the screw 34.

Thus, in the present embodiment, the insulating distance Lsl (Lsh) between the outer edge of the contact region 36 and the first low-voltage circuit region 42a (first high-voltage circuit region 44a) on the front surface of the double-sided circuit board is determined separately from the insulating distance Lrl (Lrh) between the head 34a of the screw 34 and the first low-voltage circuit region 42b (second high-voltage circuit region 44b) on the rear surface. Therefore, the degree of freedom is enhanced in determining the insulating distances.

### Third Embodiment

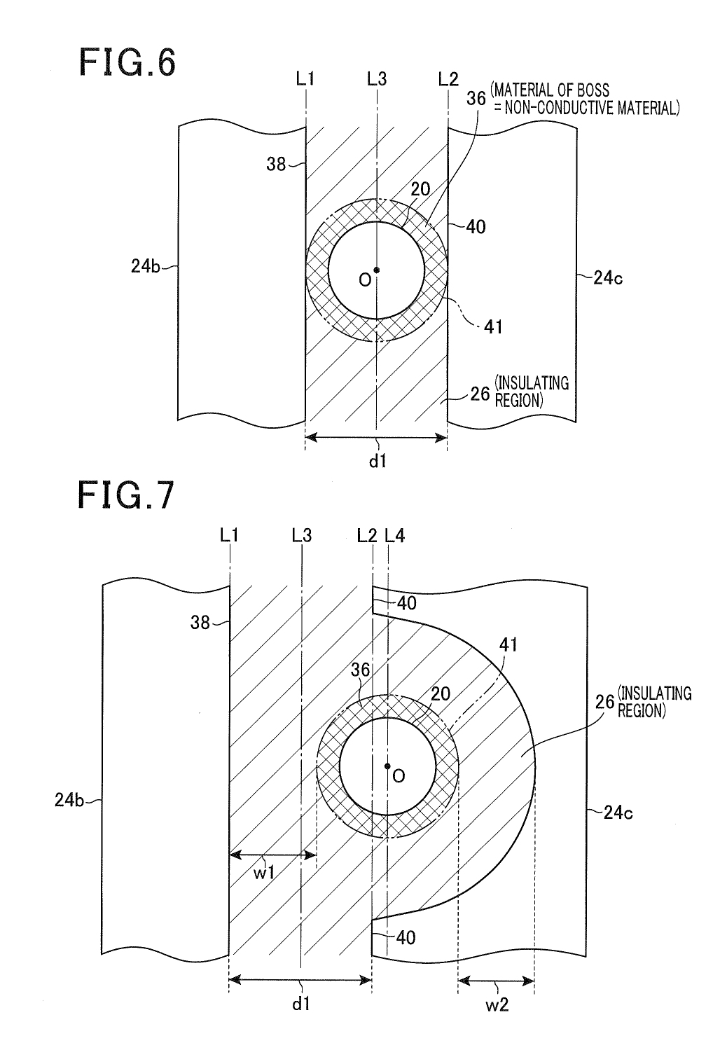

Referring to FIG. 6, a third embodiment of the present invention is described focusing on the differences from the first embodiment.

In the present embodiment, each boss 32 is made of a non-conductive material (e.g., resin). Accordingly, the contact region 36 on the circuit board 10 is electrically non-conductive.

FIG. 6 shows a mode of arranging the contact region 36 in the insulating region 26 on the circuit board 10 according to the third embodiment. FIG. 6 is an enlarged view corresponding to the enlarged view of FIG. 4 in the vicinity of the through hole 20 between the second and third high-voltage circuit regions 24b and 24c shown in FIG. 2. In FIG. 6, the region indicated by the diagonal lines is the insulating region 26.

As shown in FIG. 6, in the present embodiment, the contact region 36 is in contact with the second and third high-voltage circuit regions 24b and 24c. In this case as well, insulation breakdown is unlikely to occur between the second and third high-voltage circuit regions 24b and 24c via the contact region 36. Thus, the contact region 36 (mounting region 41) may be brought into contact with the opposed boundary lines of the respective adjacent second and third high-voltage circuit regions 24b and 24c. In the present embodiment, the boundary lines coincide with the virtual lines L1 and L2.

As described above, in the present embodiment, each boss 32 is made of a non-conductive material. Accordingly, the area for mounting electronic components on the circuit board 10 is favorably suppressed from being limited by the provision of the mounting region 41.

### Fourth Embodiment

Referring to FIG. 7, a fourth embodiment of the present invention is described focusing on the differences from the first embodiment.

The position of forming each through hole 20 is not limited to the one exemplified in the first embodiment. For example, as shown in FIG. 7, each through hole 20 may be formed so that its center O is positioned on a reference line L4 which is parallel with and offset from the center line L3. However, in this case, the following region is included in the insulating region 26. This region is defined between the outer edge of a circle having a radius w1 (=w2)+d1/2 and the outer edge of the mounting region 41.

The radius w1 (=w2)+d1/2 in this case is larger than the distance between the center O of the through hole 20 and the outer edge of the mounting region 41. Thus, in order to prevent limitation of an area for mounting electronic components as much as possible, it is desirable that the degree of offsetting the reference line L4 passing through the center O from the center line L3 is lowered as much as possible.

### Modifications

The embodiments described above may be modified as follows.

In the second embodiment, formation of each boss 32 with a non-conductive material can reduce the constraints in determining the distance Lsl between the outer edge of the contact region 36 and the first low-voltage circuit region 42a, and the distance Lsh between the outer edge of the contact region 36 and the first high-voltage circuit region 44a. Thus, the values of the distances Lsl and Lsh are made smaller than those in the second embodiment. Alternatively, only a tip end portion of each boss 32 may be made of a non-conductive material.

The mounting members (bosses) of the housing are not necessarily required to be integrated into the housing but may be provided separately from the housing.

Each through hole in a plan view of the circuit board may have not only a circular shape (true circular shape) but also an elliptical shape, a rectangular shape, or the like. Also, each boss may have not only a cylindrical shape but also a shape of a rectangular solid extending along the central axis.

The way of mounting the housing on the circuit board is not limited to the one exemplified in the above embodiments. For example, the housing may have columnar portions integrally formed with the housing and extending from the housing toward the circuit board. The columnar portions may be provided with respective claws at the ends thereof, which claws extend obliquely outward from the center axis of the respective columnar portions. These claws may be inserted into respective through holes formed in the circuit board for engagement therewith, so that the housing is mounted on the circuit board. Alternatively, when the housing is provided with columnar portions integrally formed with the housing and extending from the housing toward the circuit board, an adhesive means (adhesive agent) may be intervened between an end of each of the columnar portions and the circuit board, to thereby mount the housing on the circuit board.

In the circuit configuration of the first embodiment, the potential difference that would be caused between adjacent circuit regions has four different maximum values (Vmax, Vmax−Vmin, Vmax−VL and VL−Vmin). However, the maximum values are not limited to these four maximum values. For example, the potential difference may have N number of different maximum values (N is an integer of five or more). In this case, for example, an average of the maximum values of the potential difference between the adjacent circuit regions may be defined to be an average potential difference. Further, in this case, adjacent circuit regions having a large potential difference may be defined as being adjacent circuit regions having a maximum potential difference, which is larger than the average potential difference. Also, adjacent circuit regions having low potential difference may be defined as being adjacent circuit regions having a maximum potential difference, which is lower than the average potential difference.

The two opposed boundary lines (e.g., lines L1 and L2 of FIG. 6) of adjacent circuit regions are not limited to linear lines but may be curved lines.

The present invention may be applied not only to plug-in hybrid vehicles (PHV) but also to electric vehicles (EV) only having a rotary machine as an on-vehicle main engine, for example.

The present invention may be embodied in several other forms without departing from the spirit thereof. The embodiments and modifications described so far are therefore intended to be only illustrative and not restrictive, since the scope of the invention is defined by the appended claims rather than by the description preceding them. All changes that fall within the metes and bounds of the claims, or equivalents of such metes and bounds, are therefore intended to be embraced by the claims.

What is claimed is:

1. An electronic apparatus, comprising:
a circuit board on which a plurality of electronic components are mounted; and
a housing that is provided on the circuit board,
wherein
the housing includes
a mounting member that mounts the housing on the circuit board, and the circuit board includes
a plurality of circuit regions where the plurality of electronic components are included, the plurality of circuit regions being spaced from one another,
an insulating region that is located between adjacent circuit regions of the plurality of circuit regions to insulate between the adjacent circuit regions, and
a mounting region where the mounting member is mounted on the circuit board, the mounting region being provided in the insulating region located between the adjacent circuit regions in a state where the housing is mounted on the circuit board.

2. The electronic apparatus according to claim 1, wherein:
the adjacent circuit regions of the plurality of circuit regions includes first adjacent circuit regions and second adjacent circuit regions, where a potential difference between the first adjacent circuit regions is larger than a potential difference between the second adjacent circuit regions; and
the mounting member is provided in the insulating region located between the first adjacent circuit regions.

3. The electronic apparatus according to claim 1, wherein:
a through hole, through which a screw is inserted, is formed in the insulating region located between the adjacent circuit regions;
a screw hole, in which the screw is inserted via the through hole, is formed in the mounting member;
the mounting region is a region that is enclosed by an outer edge of a portion of the mounting member in contact with the circuit board in a state where the housing is mounted on the circuit board by inserting the screw in the screw hole via the through hole; and
a center of the through hole is positioned on a central line passing through a central portion between a pair of lines that are determined by passing through parts of a pair of boundary lines of the adjacent circuit regions, the parts of the pair of boundary lines being opposed to and parallel with each other.

4. The electronic apparatus according to claim 3, wherein:
the mounting member is made of conductive material; and
the insulating region includes a region that is enclosed by an outer edge of the mounting member and a predetermined closed curve which is positioned outside from the outer edge of the mounting member on the circuit board and is determined by enclosing the mounting member.

5. The electronic apparatus according to claim 1, wherein:
the mounting member is made of non-conductive material; and
the mounting region is a region that is enclosed by an outer edge of a portion of the mounting member in contact with the circuit board in a state where the housing is mounted on the circuit board.

6. The electronic apparatus according to claim 1, wherein:
the circuit board is a double-sided circuit board having a first surface and a second surface, the second surface being a rear surface with respect to the first surface, the plurality of electronic components being mounted on each of the first surface and the second surface;
the plurality of circuit regions and the insulating region are mounted on each of the first surface and the second surface;
a through hole, through which a screw is inserted, is formed in the insulating region located between the adjacent circuit regions;
a screw hole, in which the screw is inserted via the through hole, is formed in the mounting member;
the housing is mounted on the circuit board by inserting the screw in the screw hole via the through hole from a side of the second surface to a side of the first surface;
the mounting region includes a first region and a second region, where the first region is a region that is enclosed by an outer edge of a portion of the mounting member in contact with the first surface in a state where the housing is mounted on the circuit board, and the second region is a region that is enclosed by an outer edge of a portion of a head of the screw in contact with the second surface in a state where the housing is mounted on the circuit board; and
a first insulating distance and a second insulating distance are individually determined, where the first insulating distance is an insulating distance between the adjacent circuit regions between which the first region is placed and the second insulating distance is an insulating distance between the adjacent circuit regions between which the second region is placed.

7. The electronic apparatus according to claim 1, wherein:
a through hole, through which a screw is inserted, is formed in the insulating region located between the adjacent circuit regions;
a screw hole, in which the screw is inserted via the through hole, is formed in the mounting member;
the housing is mounted on the circuit board by inserting the screw in the screw hole via the through hole; and
the through hole is formed at positions which are aligned on the circuit board.

8. The electronic apparatus according to claim 7, wherein:
the positions of through hole are determined by a condition that maximizes vibration resistance of the circuit board that refers to proof stress of the circuit board which can retain reliability of the circuit board when an external force is applied to the electronic apparatus.

9. The electronic apparatus according to claim 1, wherein:
a through hole, through which a screw is inserted, is formed in the insulating region located between the adjacent circuit regions;
a screw hole, in which the screw is inserted via the through hole, is formed in the mounting member;
the mounting region is a region that is enclosed by an outer edge of a portion of the mounting member in contact with the circuit board in a state where the housing is mounted on the circuit board by inserting the screw in the screw hole via the through hole; and
a center of the through hole is positioned on a reference line which is parallel with and offset from a central line passing through a central portion between a pair of lines that are determined by passing through parts of a pair of boundary lines of the adjacent circuit regions, the parts of the pair of boundary lines being opposed to and parallel with each other.

10. The electronic apparatus according to claim 1, wherein:
the circuit board is a circuit board for a power converter.

11. The electronic apparatus according to claim 10, wherein:
the power converter is mounted on a vehicle.

12. The electronic apparatus according to claim 10, wherein
the power converter includes:
a converter that converts direct current (DC) voltage from a battery to a predetermined DC voltage under drive control of switching elements through drive circuits;
an inverter that converts the predetermined DC voltage from the converter to an alternating current (AC) voltage under control of switching elements through drive circuits; and
a control circuit that controls the inverter and the step-up converter.
